(19) United States
(12) Patent Application Publication
(10) Pub. No.: US 2018/0041293 A1
(43) Pub. Date: Feb. 8, 2018

(54) APPARATUS FOR AUTOMATICALLY MEASURING PIM

(71) Applicant: GAMMANU CO., LTD., Hwaseong-si, Gyeonggi-do (KR)

(72) Inventor: Ho Byung CHA, Hwaseong-si (KR)

(73) Assignee: Gammanu Co., Ltd., Hwaseong-si, Gyeonggi-do (KR)

(21) Appl. No.: 15/551,579

(22) PCT Filed: Nov. 6, 2015
(86) PCT No.: PCT/KR2015/011902

§ 371 Date: Aug. 16, 2017

(30) Foreign Application Priority Data
Feb. 17, 2015 (KR) 10-2015-0024234

(51) Int. Cl. H04B 17/345; G01R 23/20

(52) U.S. Cl. CPC H04B 17/345; G01R 23/20; G01R 29/10

(57) ABSTRACT

The present invention relates to an apparatus for automatically measuring PIM, the apparatus comprising: at least one first connector formed on the upper surface of a plate; at least one first movement control unit, formed on the upper surface of the first plate, for controlling movement of the first connector; a second plate formed on the lower surface of the first plate; at least one second connector formed on the lower surface of the second plate; and at least one second movement control unit, formed on the rear surface of the second plate, for controlling movement of the second connector. The present invention is capable of measuring PIM of all RF components regardless of the port form of the RF components, and thus can reduce time and costs incurred for individually designing and purchasing PIM measurement apparatuses or jigs according to the port form of RF components. Also, the present invention is capable of automatically connecting connectors of a PIM measurement apparatus to ports of RF components without requiring human effort, and thus has an effect of reducing unnecessary effort and the time taken therefor. In addition, the present invention has an effect of, when changing a phase of a signal radiated by an RF component, conveniently changing a phase by means of only inputting a desired changed phase, even if a human does not individually rotate a motor so as to change the phase.

### TECHNICAL FIELD

The present invention relates to a passive intermodulation (PIM) automatic measurement device, and more particularly, to a PIM automatic measurement device in which one or more first connectors and one or more second connectors are automatically connected to ports of a radio frequency (RF) component, thus enabling PIM measurement.

### BACKGROUND ART

Passive intermodulation (PIM) is a phenomenon in which, when signals at two or more frequencies are input to a passive device, signals of other unintended frequencies are generated in addition to the two or more signals, and PIM commonly occurs in RF components such as an antenna using multiple frequency bands. Due to this, the quality of wireless communication deteriorates, and, in severe cases, wireless communication may fail, and thus it is necessary to previously measure PIM to produce antennas, and problems occurring therefrom have to be addressed.

In conventional PIM measurement devices, a PIM measurement device or a zig is individually designed and produced according to the type of port included in an RF component such as an antenna, and antenna manufacturers should individually purchase and use an expensive PIM measurement device or zig according to the type of antenna port, and thus unnecessary time and cost are consumed.

In addition, when connecting a PIM measurement device to an RF component, a user must individually connect a connector of the PIM measurement device and a port of the RF component, and also individually change the phase of a signal emitted from the RF component by operating a motor, and thus unnecessary time and effort are required.

Therefore, the present invention provides a novel PIM automatic measurement device that may be generally used in all RF components regardless of the type of ports of the RF components, does not require a user to put effort into connecting a connector of the PIM measurement device and a port of an RF component through automatic connection therebetween, and may conveniently change the phase of a signal emitted from the RF component without being individually changed by a user by operating a motor.

### DISCLOSURE

### Technical Problem

Therefore, the present invention has been made in view of the above problems, and it is one object of the present invention to provide a PIM automatic measurement device that may be generally used in all RF components regardless of the type of ports of RF components for PIM measurement.

It is another object of the present invention to provide a PIM automatic measurement device that does not require a user to put effort into connecting a connector of the PIM measurement device to a port of an RF component, through automatic connection therebetween.

It is yet another object of the present invention to provide a PIM automatic measurement device that enables a user to conveniently change the phase of a signal emitted from an RF component instead of changing the phase of the signal by individually operating a motor.

Meanwhile, the present invention is not limited to the technical goals set forth above and other technical goals may be inferred from the following description within a range obvious to those of ordinary skill in the art.

### Technical Solution

A PIM automatic measurement device according to an embodiment of the present invention includes: one or more first connectors disposed on an upper surface of a first plate; one or more first movement controllers disposed on the upper surface of the first plate to control movement of the one or more first connectors; a second plate disposed on a lower surface of the first plate; one or more second connectors disposed on the lower surface of the second plate; and one or more second movement controllers disposed on a rear surface of the second plate to control movement of the one or more second connectors. According to the present invention, PIM of all RF components may be measured regardless of the type of ports of the RF components, and thus time and cost consumed in individually designing and purchasing a PIM measurement device or a zig according to the type of port of an RF component may be reduced. In addition, the PIM automatic measurement device does not require that a user put effort into connecting a connector of the PIM measurement device to a port of an RF component through automatic connection therebetween, and thus unnecessary time and effort consumed therein may be reduced. In addition, the phase of a signal emitted from an RF component may be conveniently changed by a user by simply inputting desired phase instead of changing the phase of the signal by individually operating a motor.

In addition, the PIM automatic measurement device may further include one or more first connection parts disposed on the upper surface of the first plate, one end of the first connection part being connected to the first connector and another end thereof is connected to the first movement controller, and the first connector may be connected to the first connection part by a plate spring.

In addition, the PIM automatic measurement device may further include one or more first rail parts disposed on the upper surface of the first plate to allow the first connection part to move either forward or backward, one or more second connection parts disposed on the lower end of the first plate, one end of the second connection part being connected to the second plate and another end thereof being connected to the second movement controller, one or more second rail parts disposed on a lower surface of the first plate to allow the second plate to move either forward or backward, a third plate disposed at a lower end of the second connector to support the second connector, and a fixing part connecting the second plate and the third plate to each other to be fixed. The first movement controller and the second movement controller may be configured as any one of an air cylinder, a hydraulic pump, and an electric motor.

Meanwhile, the second connector may further include a remote electrical tilt (RET) motor to tilt a phase of a signal emitted from an antenna, upward/downward height adjustment and leftward/rightward movement of the first and second connectors may be enabled, and the PIM automatic measurement device may further include a shelf part allowing an radio frequency (RF) component having one or more ports connected to the first and second connectors to be mounted thereon. In this regard, the shelf part further may include a vibrator to vibrate the RF component, and the PIM automatic measurement device may further include a cover member including the shelf part therein, an inner wall of the cover member being filled with an electromagnetic wave absorbing material.

Lastly, the PIM automatic measurement device may further include a first controller to control ON/OFF of the first and second movement controllers and a second controller to control a tilt angle of the RET motor.

### Advantageous Effects

According to the present invention, a PIM measurement device can measure PIM of all RF components regardless of the type of ports of the RF components, and thus time and cost consumed in individually designing and purchasing a PIM measurement device or a zig according to the type of port of an RF component can be reduced.

In addition, the PIM measurement device does not require that a user put effort into connecting a connector of the PIM measurement device to a port of an RF component through automatic connection therebetween, and thus unnecessary time and effort consumed therein can be reduced.

In addition, the phase of a signal emitted from an RF component can be conveniently changed by a user by simply inputting desired phase instead of changing the phase of the signal by individually operating a motor.

Meanwhile, effects of the present invention are not limited to the effects set forth herein, and various other effects may be inferred from the following description within a range obvious to those of ordinary skill in the art.

### DESCRIPTION OF DRAWINGS

FIG. 1 is a top view of a PIM automatic measurement device according to an embodiment of the present invention.

FIG. 2 is a front view of the PIM automatic measurement device according to an embodiment of the present invention.

FIG. 3 is a view of antenna ports for PIM measurement.

FIG. 4 is a view of a plate spring involved in height adjustment and leftward/rightward movement of a first connector.

FIG. 5 is a view illustrating a state before the first connector is moved forward by a first movement controller.

FIG. 6 is a view illustrating a state in which the first connector is being moved forward by the first movement controller.

FIG. 7 is a side view of the PIM automatic measurement device according to an embodiment of the present invention.

FIG. 8 is a view illustrating a state before a second connector is moved forward by a second movement controller.

FIG. 9 is a view illustrating a state in which the second connector is being moved forward by the second movement controller.

FIG. 10 is a view of a cover member including a shelf part.

FIG. 11 is a view of a first controller.

FIG. 12 is a view illustrating a state in which the PIM automatic measurement device according to an embodiment of the present invention is mounted on a support and connected to one end of a cover member.

Meanwhile, reference numerals used in the drawings are as follows:

100: PIM automatic measurement device

10: first plate

20: first connector

21: coaxial cable 25: first connection part

26: plate spring 28: second rail part

30: first movement controller

40: second plate

50: second connector

55: second connection part

60: second movement controller

70: third plate

82: shelf part 83: cover member 87: first controller

### MODE

Hereinafter, some embodiments of the present invention will be described in detail with reference to the accompanying drawings. The embodiments set forth herein are provided so that the spirit of the present invention can be understood by those of ordinary skill in the art without undue difficulty, and the present invention is not limited to the embodiments. Detailed explanations of related known configurations or functions will be omitted when such detailed explanations might unnecessarily obscure the essence of the invention.

In addition, the details illustrated in the accompanying drawings are intended to clearly explain embodiments of the present invention and thus the shapes thereof may be different from actual shapes thereof, and it should be noted that the same reference numerals in each drawing possibly denote the same elements although illustrated in other drawings.

In addition, it will be understood that the expression “including” certain elements as used herein is an open expression and simply refers to the presence of the corresponding elements, but does not preclude the presence of additional elements.

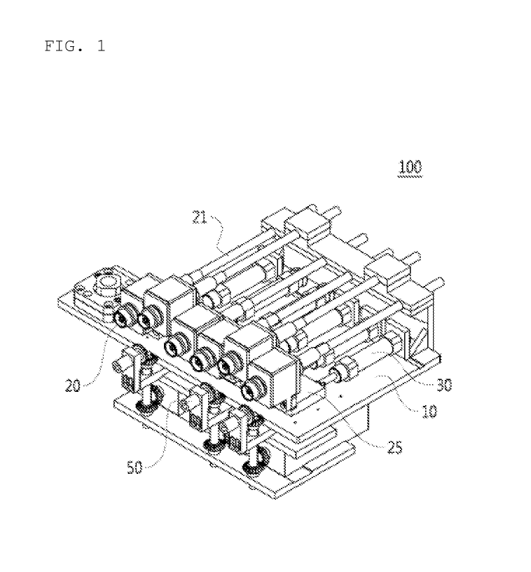

FIG. 1 is a top view of a PIM automatic measurement device 100 according to an embodiment of the present invention.

The PIM automatic measurement device 100 includes a first plate 10, a first connector 20, a first movement controller 30, a second plate 40, a second connector 50, and a second movement controller 60, and an upper surface of the PIM automatic measurement device 100 includes the first plate 10, the first connector 20, and the first movement controller 30.

Meanwhile, an RF component may include all components that emit RF signals, but, in the present specification, an antenna will be described as the RF component for clarity of explanation.

The first plate 10 is a configuration positioned at the center of the PIM automatic measurement device 100 according to an embodiment of the present invention, in which the first connector 20 is positioned on an upper surface of the first plate 10, and the second connector 50 is positioned on a lower surface thereof. This will be described below in detail in the corresponding description. The first plate 10 has to support structures disposed on the upper surface thereof such as the first connector 20, the first movement controller 30, and the like, and thus may be made of a metal material with predetermined thickness and hardness sufficient to support the weights of the structures. For example, the first plate 10 may be made of a hard metal material such as an iron or aluminum alloy or the like, having a thickness of 2 cm to 3 cm, and the metal material and thickness of the first plate 10 may be appropriately adjusted.

Meanwhile, the first plate 10 may have a sufficient area to include all the structures positioned on the upper surface of the first plate 10, but, to minimize an overall size of the PIM automatic measurement device 100, may have an area such that the size of an empty space where no structures are disposed may be minimized.

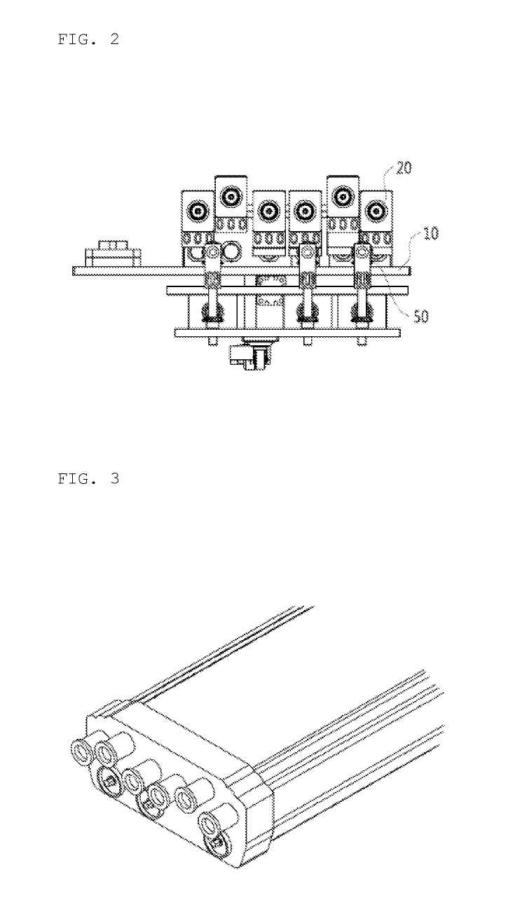

The first connector 20 is positioned on the upper surface of the first plate 20. In particular, the first connector 20 is configured in a certain arrangement form such that one or more first connectors 20 are connected to one or more first connection parts 25. Referring to FIG. 2, it can be confirmed that the first connector 20 is configured in a certain arrangement form, and, assuming that connectors are denoted as 1^{st} to 6^{th} connectors from the first connector 20 on the left side, the 2^{nd} and 5^{th} connectors protrude upward more than the remaining connectors. Such arrangement of the first connectors 20 corresponds to arrangement of upper ports of an antenna to which the first connectors 20 are connected. That is, in the case of ports (e.g., 1^{st} to 6^{th} ports) of an antenna of FIG. 3, connected to the first connectors 20 of FIG. 2, the 2^{nd} to 5^{th} ports also protrude upward more than the other ports. In addition, upward/downward height adjustment and leftward/rightward movement of the first connectors 20 may be performed by a rail (not shown) and a plate spring 26 formed at one end of the first connector 25, which will be described below, and thus, even when an antenna for PIM measurement has a different arrangement of ports from that illustrated in FIG. 3, the first connectors 20 may be connected to the PIM automatic measurement device 100 without any difficulty. Through such configuration, time and cost consumed in designing and purchasing a separate PIM measurement device for measuring PIM of an antenna including different port arrangement may be reduced. Meanwhile, one or more coaxial cables 21 are connected to rear surfaces of the first connectors 20 to provide feed signals for operating an antenna connected for PIM measurement.

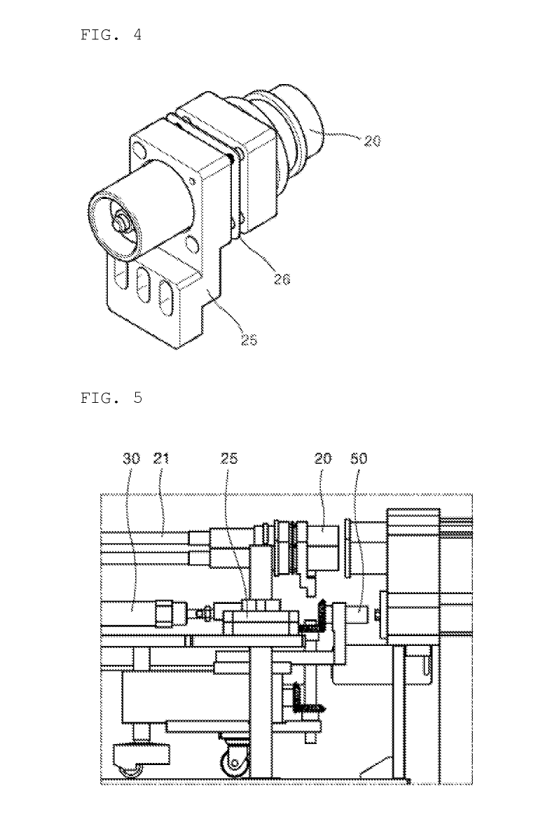

The first connection part 25 is configured in singular or plural on the upper surface of the first plate 10 to connect the first connectors 20 to the first movement controller 30, which will be described below. In particular, the first connection part 25 may be provided in the same number as that of the first connectors 20, and one end of the first connection part 25 is connected to the first connector 20, and another end thereof is connected to the first movement controller 30. In addition, a rail (not shown) with a predetermined shape may be provided at one end of the first connection part 25 connected to the first connector 20 to enable upward/downward height adjustment and leftward/rightward movement of the first connectors 20. That is, the height adjustment and leftward/rightward movement of the first connectors 20 may be performed by a rail (not shown) formed at one end of the first connection part 25. Due to this, the first connection part 25 may be provided in the same number as that of the first connectors 20. This is because, when two or more first connectors 20 are simultaneously connected to the first connection part 25, there is the possibility of unnecessary collision between the two or more first connectors 20 when performing height adjustment and leftward/rightward movement. However, on the premise that there is no collision between the two or more first connectors 20 simultaneously connected to the first connection part 25 due to non-overlapping of leftward/rightward movement paths, the first connection part 25 may be provided in number different from that of the first connectors 20, if necessary. Meanwhile, the first connector 20 may be provided, at a rear surface thereof, with a groove with a predetermined depth at a position corresponding to a rail formed at one end of the first connection part 25, thereby smoothly performing the height adjustment and leftward/rightward movement of the first connectors 20. In addition, the first connection part 25 may also be provided, at one end thereof, with other means for guiding height adjustment and leftward/rightward movement of the first connectors 20, in addition to a rail (not shown) with a predetermined shape. For example, as illustrated in FIG. 4, the first connection part 25 may be provided with the plate spring 26 at one end thereof. In particular, the plate spring 26 is disposed between the first connection part 25 and the first connector 20, and enables height adjustment and leftward/rightward movement of the first connectors 20. In this case, different from the case of using a rail (not shown), there is no need to form a groove with a predetermined depth at a rear surface of the first connector 20, and thus manufacturing processes may be simplified and manufacturing costs may be reduced.

Meanwhile, the first connection part 25 may be positioned on one or more first rail parts (not shown) disposed on the upper surface of the first plate 10 and move either forward or backward. In this case, the first connection part 25 may be provided, at a lower surface thereof, with a groove with a predetermined depth formed at a position corresponding to the first rail part (not shown), and thus may smoothly move either forward or backward. In particular, when the first connection part 25 moves forward, the first connector 20 connected to the one end of the first connection part 25 may be connected to a port of an antenna for PIM measurement and, when the first connection part 25 moves backward, the first connector 20 may be disconnected from the port of the antenna. That is, the first rail part (not shown) may guide forward/backward movement paths of the first connection part 25 and thus enable the first connector 20 to be connected to or disconnected from the port of an antenna. Meanwhile, it should be understood that the first rail part (not shown) is formed on the upper surface of the first plate 10, and the first connection part 25 is formed thereon, and thus the first rail part is not shown in the drawings and, accordingly, is not specifically illustrated in the accompanying drawings, but the first rail part (not shown) should be regarded as being formed in all the drawings. In addition, the first plate 10 is provided with one or more second rail parts 28 at the lower surface of the first plate 10, and a detailed description thereof will be provided below in the corresponding description.

The one or more first connectors 20 may be connected to one end of the one or more first connection parts 25, and thus the upward/downward height adjustment and leftward/rightward movement thereof are enabled by a rail (not shown) and the plate spring 26. In addition, the first connector 20 may be connected to or disconnected from a port of an antenna as the first connection part 25 formed on the first rail part (not shown) moves either forward or backward. Thus, it is very important to control the forward/backward movement of the first connection part 25, and thus the first movement controller 30 that enables this will now be described.

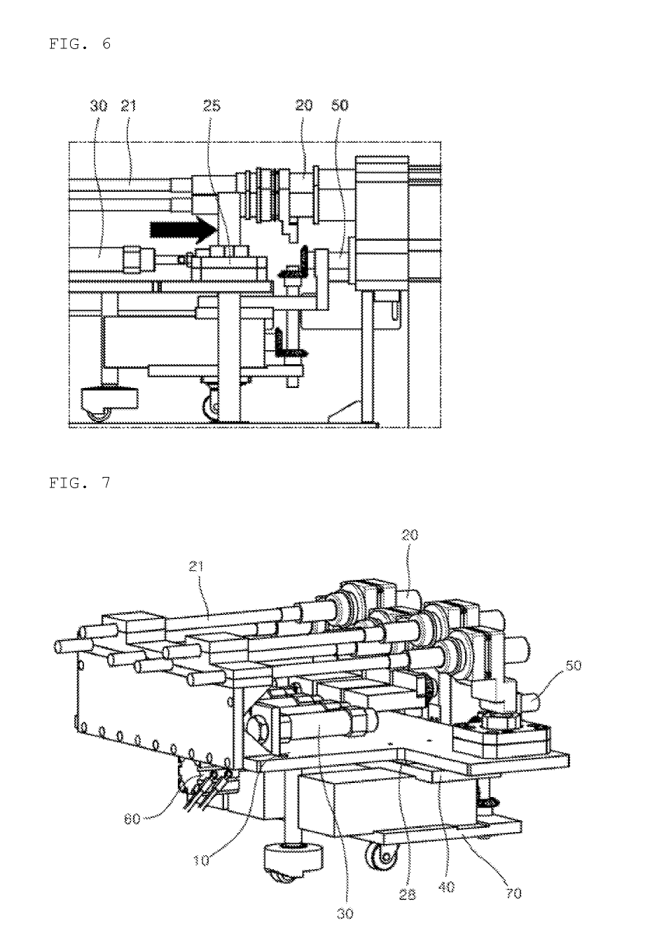

The first movement controller 30 is configured in singular or plural on the upper surface of the first plate 10, and controls forward or backward movement of the first connector 20. In particular, when the first movement controller 30 is in an ON-state through connection to another end of the first connection part 25, one end of which is connected to the first connector 20, the first connection part 25 is itself moved and, accordingly, the first connector 20 may also move together with the first connection part 25. Referring to FIGS. 5 and 6, it can be confirmed that, when the first movement controller 30 is in an ON-state, the first connection part 25 and the first connector 20 simultaneously move forward, and the first connector 20 is automatically connected to a port of an antenna for PIM measurement.

Meanwhile, the first movement controller 30 may be selected from any one of air cylinders, hydraulic pumps, and electric motors, the first connection part 25 may be moved only by movement of the first movement controller 30 itself, but may be moved by a predetermined bar (not shown) additionally disposed between the first movement controller 30 and the first connection part 25. For example, when the first movement controller 30 is configured as an air cylinder, a bar (not shown) may be moved forward by instantaneously injecting air into the cylinder, and, accordingly, the first connection part 25 and the first connector 20 may move forward. In addition, when the first movement controller 30 is configured as a hydraulic pump, similarly, a bar (not shown) may be moved forward by applying pressure to the inside of the pump, and, accordingly, the first connection part 25 and the first connector 20 may move forward. Lastly, when the first movement controller 30 is configured as an electric motor, a bar (not shown) may be moved forward by operation of the motor, and, accordingly, the first connection part 25 and the first connector 20 may move forward. As such, as the first connection part 25 moves forward by the first movement controller 30, the first connector 20 connected to one end of the first connection part 25 may be automatically connected to a port of an antenna for PIM measurement. In particular, in a state in which the pressure applied to the inside of the air cylinder or the hydraulic pump is maintained or the electric motor is being operated, while fixing the first connection part 25 forward, a state in which the first connector 20 is connected to the port of an antenna may be continuously maintained. In contrast, when the first movement controller 30 is in an OFF state, the first connector 20 is disconnected from the port of an antenna. For example, in a case in which the first movement controller 30 is configured as an air cylinder, when the first movement controller 30 is in an OFF state, air injected into the cylinder is discharged and thus a bar (not shown) moves from front to back and, accordingly, the first connection part 25 also moves backward, resulting in disconnection of the first connector 20 from the port of an antenna. In addition, in a case in which the first movement controller 30 is configured as a hydraulic pump, similarly, the pressure inside the pump is decreased and thus a bar (not shown) moves from front to back and, accordingly, the first connection part 25 also moves backward, resulting in disconnection of the first connector 20 from the port of an antenna. Lastly, in a case in which the first movement controller 30 is configured as an electric motor, the motor operates in a direction opposite to that in which the motor pushes a bar (not shown) forward and thus the bar (not shown) moves from front to back and, accordingly, the first connection part 25 also moves backward, resulting in disconnection of the first connector 20 from the port of an antenna. Meanwhile, it is obvious that such forward or backward movement of the first connection part 25 is performed on the first rail part (not shown).

As described above, according to the ON/OFF state of the first movement controller 30, the bar (not shown) or the first connection part 25 may move either forward or backward and, accordingly, the first connector 20 may be automatically connected to or disconnected from the port of an antenna for PIM measurement. Thus, a connector of the PIM measurement device and a port of an antenna for PIM measurement may be automatically and conveniently connected to and disconnected from each other without requiring efforts of a user. In addition, the first movement controller 30 may be configured as any means for applying a predetermined pressure so that the bar (not shown) or the first connection part 25 and the first connector 20 move forward, in addition to the air cylinder, the hydraulic pump, or the electric motor as described above.

A detailed description of the first connector 20 disposed on the upper surface of the first plate 10 of the PIM automatic measurement device 100 according to an embodiment of the present invention and connected to a port of an antenna for PIM measurement and the first movement controller 30 to control forward or backward movement of the first connector 20 has been provided. Hereinafter, configurations related to the second connector 50 capable of changing the phase of a signal emitted from an antenna for PIM measurement will be described. This is another major part of configurations of the present invention and is related to configurations formed on a lower end of the first plate 10.

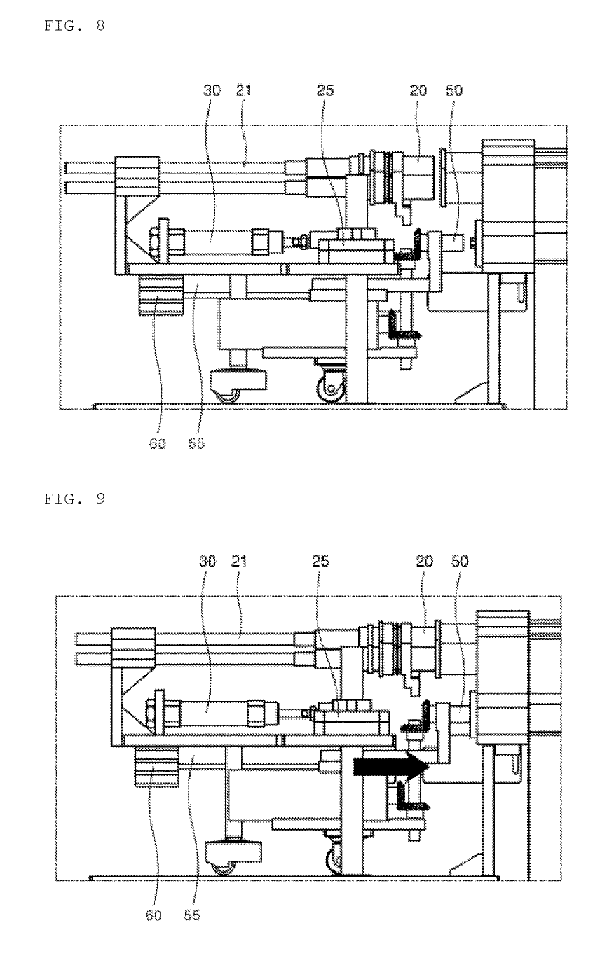

FIG. 7 is a side view of the PIM automatic measurement device 100 according to an embodiment of the present invention. Referring to FIG. 7, the second plate 40, the second connector 50, and the second movement controller 60 that are disposed at a lower end of the first plate 10 can be confirmed.

The second plate 40 is disposed on the lower end of the first plate 10. In particular, one or more second rail parts 28 disposed on the lower surface of the first plate 10 are provided with a groove with a predetermined depth that allows forward or backward movement. In addition, the second plate 40 does not include predetermined configurations on an upper surface thereof as in the first plate 10, and is a configuration that is moved either forward or backward simply by the second movement controller 60, which will be described below, and thus has a smaller area than that of the first plate 10, thereby minimizing the overall size of the PIM automatic measurement device 100.

The second connector 50 is configured in singular or plural at a lower end of the second plate 40, and, in particular, is supported by a third plate 70 disposed at a lower end of the second connector 50. That is, as illustrated in FIG. 7, the second connector is disposed between the second plate 40 and the third plate 70. In addition, the second connector 50 has to move together as the second plate 40 moves either forward or backward, and thus an upper surface of the second connector 50 may be strongly connected to a lower surface of the second plate 40 via a predetermined structure. For example, the upper surface of the second connector 50 and the lower surface of the second plate 40 may be fastened with a bolt or may be connected by a predetermined adhesive. In another embodiment, instead of connecting the lower surface of the second plate 40 to the upper surface of the second connector 50, an additional means such as a fixing part (not shown) that connects the second plate 40 and the third plate 70 to each other may be configured so that the third plate 70 moves together with movement of the second plate 40 and, accordingly, the second connector 50 supported by the third plate moves therewith. That is, in any case, the second plate 40 is the center of movement, and the second plate 40 may be connected to the second connector 40 or the third plate 70.

Meanwhile, the second connector 50 is connected to a phase modification port of an antenna for PIM measurement. Generally, an antenna including multiple ports includes a separate phase modification port for adjusting the phase of a signal emitted from the antenna, and the second connector 50 may be connected to a lower port from among ports of an antenna for PIM measurement illustrated in FIG. 3. In addition, the second connector 50 may also be configured in the same manner as in the first connector 20 described above so as to enable upward/downward height adjustment and leftward/rightward movement, and thus may be connected to the PIM automatic measurement device 100 without any problem even when an antenna for PIM measurement includes a phase modification port arrangement different from what is illustrated in FIG. 3.

In addition, the second connector 50 is connected to the phase modification port of an antenna for PIM measurement, and thus includes a predetermined driving means capable of tilting the phase of a signal emitted from the antenna. The driving means may be a motor, in particular, a remote electrical tilt (RET) motor. Referring to FIG. 6, it can be confirmed that an additional configuration with a rectangular parallelepiped shape is disposed at a rear surface of the second connector 50, and a driving means may be inserted thereinto. Meanwhile, the second connector 50 may also include any driving means capable of tilting the phase of a signal emitted from an antenna, in addition to the RET motor.

The second connection part 55 is configured in singular or plural at the lower end of the first plate 10, and one end of the second connection part 55 is connected to the second plate 40 and another end thereof is connected to the second movement controller 60, which will be described below. It has already been described above that, as the second plate 40 moves either forward or backward, the second connector 50 moves together. That is, the second connection part 55 serves to transmit force transmitted by the second movement controller 60 to the second plate 40. In particular, when the second movement controller 60 moves the second connection part 55 forward, the second plate 40 also moves forward, and, when the second movement controller 60 moves the second connection part 55 backward, the second plate 40 also moves backward. That is, the second connection part 55 is a configuration such as a predetermined bar (not shown) described above with respect to the first movement controller 30, and may have various shapes such as a bar shape, a plate shape, and the like. A reason why the second connection part 55 is needed is that the lower end of the first plate 10 has spatial restriction in order to minimize the overall size of the PIM automatic measurement device 100, and does not have a space sufficient for the second movement controller 60 to directly move the second plate 40, unlike the upper surface of the first plate 10. However, the second movement controller 60 may directly move the second plate 40 without the second connection part 55 so long as there is a sufficient space.

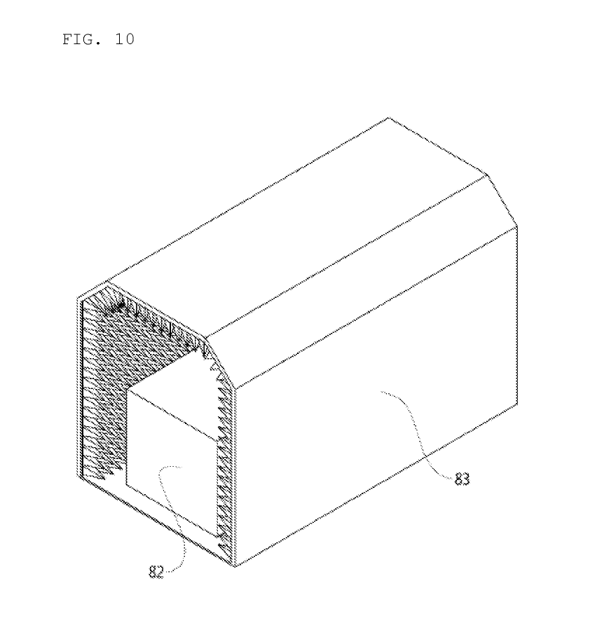

The second movement controller 60 is configured in singular or plural on the rear surface of the second plate 40 to control forward or backward movement of the second connector 50. In particular, when in an ON state via connection to another end of the second connection part 55, the second movement controller 60 moves the second connection part 55 itself, and, accordingly, the second plate 40 connected to one end of the second connection part 55 moves therewith and, consequently, the second connector 50 moves. Referring to FIGS. 8 and 9, it can be confirmed that, when the second movement controller 60 is in an ON state, the second connection part 55, the second plate 40, and the second connector 50 move in unison, and the second connector 50 is automatically connected to the phase modification port of an antenna for PIM measurement.

Meanwhile, the second movement controller 60 may also be configured by selecting any one of an air cylinder, a hydraulic pump, and an electric motor, and the second plate 40 may be moved only by movement of the second movement controller 60 itself, but the second connection part 55 may be further configured due to spatial restriction to move the second plate 40. Operation of the second movement controller 60 will now be described. For example, when the second movement controller 60 is configured as an air cylinder, the second connection part 55 may be moved forward by instantaneously injecting air into the cylinder, and, accordingly, the second plate 40 and the second connector 50 may move forward. In addition, when the second movement controller 60 is configured as a hydraulic pump, similarly, the second connection part 55 may be moved forward by applying pressure to the inside of the pump, and, accordingly, the second plate 40 and the second connector 50 may move forward. Lastly, when the second movement controller 60 is configured as an electric motor, the second connection part 55 may be moved forward by operation of the motor, and, accordingly, the second plate 40 and the second connector 50 may move forward. As such, as the second connection part 55 moves forward by the second movement controller 60, the second plate 40 connected to one end of the second connection part 55 also moves forward, and the second connector 50 may be automatically connected to the phase modification port of an antenna for PIM measurement. In particular, in a state in which the pressure applied to the inside of the air cylinder or the hydraulic pump is maintained or the electric motor is being operated, while fixing the second connection part 55 forward, a state in which the second connector 50 is connected to the phase modification port of an antenna may be continuously maintained. In contrast, when the second movement controller 60 is in an OFF state, the second connector 50 is disconnected from the phase modification port of an antenna. For example, in a case in which the second movement controller 60 is configured as an air cylinder, when the second movement controller 60 is in an OFF state, air injected into the cylinder is discharged and thus the second connection part 55 moves from front to back, and, accordingly, the second plate 40 also moves backward and thus the second connector 50 is disconnected from the phase modification port of an antenna. In addition, in a case in which the second movement controller 60 is configured as a hydraulic pump, similarly, the pressure inside the pump is decreased and thus the second connection part 55 moves from front to back and, accordingly, the second plate 40 also moves backward, resulting in disconnection of the second connector 50 from the phase modification port of an antenna. Lastly, in a case in which the second movement controller 60 is configured as an electric motor, the motor operates in a direction opposite to that in which the motor pushes the second connection part 55 forward and thus the second connection part 55 moves from front to back and, accordingly, the second plate 40 also moves backward, resulting in disconnection of the second connector 50 from the phase modification port of an antenna. Meanwhile, it is obvious that such forward or backward movement of the second plate 40 is performed on a second rail part 28.

As described above, according to the ON/OFF state of the second movement controller 60, the second connection part 55 may move either forward or backward and, accordingly, the second connector 50 connected to the second plate 40 may be automatically connected to or disconnected from the phase modification port of an antenna for PIM measurement. Thus, a connector of the PIM measurement device and a phase modification port of an antenna for PIM measurement may be automatically and conveniently connected to and disconnected from each other without requiring efforts of a user. In addition, the second movement controller 60 may also be configured as any means for applying a predetermined pressure so that the second connection part 55 or the second plate 40 and the second connector 50 move forward, in addition to the air cylinder, the hydraulic pump, or the electric motor as described above.

A detailed description of the second connector 50 disposed on the lower end of the first plate 10 of the PIM automatic measurement device 100 according to an embodiment of the present invention and connected to the phase modification port of an antenna for PIM measurement and the second movement controller 60 to control forward or backward movement of the second connector 50 has been provided. By using the second movement controller 60, there may be no need to change the phase of a signal by individually operating a motor on the phase modification port of an antenna for PIM measurement by a user as known in the art.

Meanwhile, the PIM automatic measurement device 100 according to an embodiment of the present invention may further include a shelf part 82, a vibrator (not shown), a first controller 87, and a second controller (not shown), which are additional configurations, and these additional configurations will now be described.

The shelf part 82 allows an antenna for PIM measurement, connected to the first connector 20 and the second connector 50, to be mounted thereon. In addition, as illustrated in FIG. 10, the shelf part 82 may be included in a cover member 83 having, for example, a box shape with an opening at one surface thereof to minimize ambient impact during PIM measurement. In this regard, formation of the opening of the cover member 83 is performed because the first and second connectors 20 and 50 have to be connected to a port of an antenna, and an inner wall of the cover member 83 may be filled with an electromagnetic wave absorbing material. In addition, the shelf part 82 may have a flat shape so that the antenna mounted thereon maintains a horizontal state.

Meanwhile, the shelf part 82 may further include a vibrator (not shown) to vibrate the antenna. In the case of existing PIM measurement devices, a user provides intended vibration with a hard tool, such as a hammer, to simulate an ambient environment, such as wind pressure or the like, in which antennas are actually installed. However, in the present invention, vibration may be conveniently provided to the antenna without requiring efforts of a user, and the vibrator may be configured so as to adjust the intensity of vibration, and thus a variety of ambient environments may be virtually simulated.

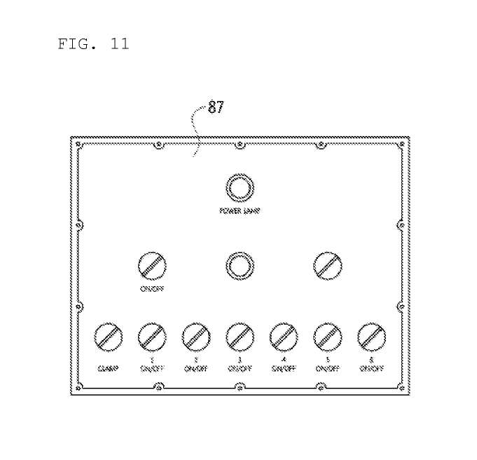

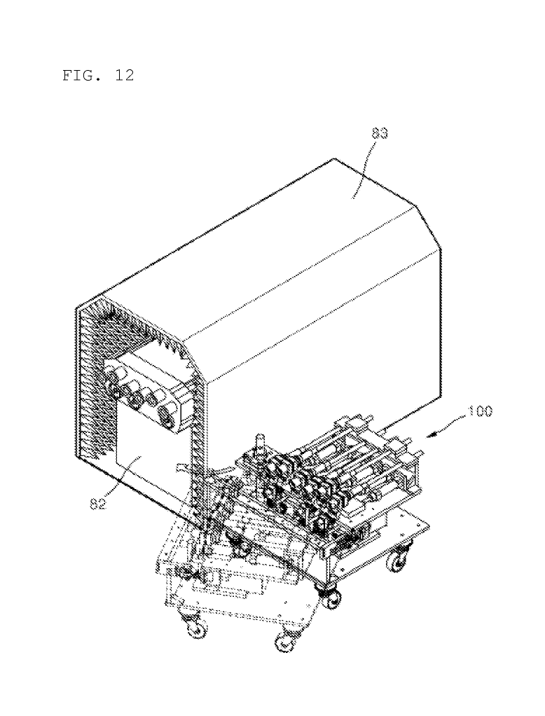

In addition, the PIM automatic measurement device 100 according to an embodiment of the present invention may further include the first controller 87 to control ON/OFF states of the first and second movement controllers 30 and 60 as described above and a driving means included in the second connector 50, in particular, the second controller (not shown) to control a tilt angle of an RET motor. In this regard, as illustrated in FIG. 11, the first controller 87 may include buttons for individually performing ON/OFF of the first and second movement controllers 30 and 60, and the second controller (not shown) may include levers capable of adjusting a predetermined angle according to an individual RET motor. In addition, the second controller (not shown) may be a configuration such as a computer with an embedded program for controlling a tilt angle of a motor. Meanwhile, the ON/OFF operation or intensity of vibration of the vibrator (not shown) may be controlled using a separate button provided on the first controller 87 or additional individual controllers. In addition, the first controller 87 and the second controller (not shown) may also be configured as a single controller.

Meanwhile, as illustrated in FIG. 12, the PIM automatic measurement device 100 according to an embodiment of the present invention may be positioned on a predetermined support and connected to one end of the cover member 83 including the shelf part 82. In particular, the support with the PIM automatic measurement device 100 positioned thereon and a connection part of the cover member 83 may be configured in an opening and closing form, such as a door. Through such configuration, after an antenna for PIM measurement is mounted on the shelf part 82 positioned in the cover member, and is positioned close to the opening of the cover member 83 by moving the support, the first and second connectors 20 and 50 may be connected to ports of an antenna through the first controller 87 and the second controller (not shown), thereby readily measuring PIM of the antenna. In this case, the support or the cover member 83 may further include a predetermined fixing member capable of fixing the support positioned close to the cover member. In addition, the support may further include a configuration such as a rotatable wheel at a lower end thereof to be movable on the ground.

The above-described embodiments of the present invention are provided only for illustrative purposes, and are not intended to limit the scope of the present invention. In addition, it is obvious to those of ordinary skill in the art to which the present invention pertains that various changes and modifications may be made within the spirit and scope of the present invention, and these changes and modifications should be construed as being within the scope of the present invention.

1. A passive intermodulation (PIM) automatic measurement device comprising:
a first plate;
one or more first connectors disposed on an upper surface of the first plate;
one or more first movement controllers disposed on the upper surface of the first plate to control movement of the one or more first connectors;
a second plate disposed on a lower end of the first plate;
one or more second connectors disposed on a lower end of the second plate; and
one or more second movement controllers disposed on a rear surface of the second plate to control movement of the one or more second connectors.

2. The PIM automatic measurement device according to claim 1, further comprising one or more first connection parts disposed on the upper surface of the first plate, one end of the first connection parts being connected to the first connector, and another end thereof being connected to the first movement controller.

3. The PIM automatic measurement device according to claim 2, wherein the first connector is connected to the first connection part by a plate spring.

4. The PIM automatic measurement device according to claim 2, further comprising one or more first rail parts disposed on the upper surface of the first plate to allow the first connection part to move either forward or backward.

5. The PIM automatic measurement device according to claim 1, further comprising one or more second connection parts disposed on the lower end of the first plate, one end of the second connection parts being connected to the second plate and another end thereof being connected to the second movement controller.

6. The PIM automatic measurement device according to claim 5, further comprising one or more second rail parts disposed on a lower surface of the first plate to allow the second plate to move either forward or backward.

7. The PIM automatic measurement device according to claim 6, further comprising a third plate disposed at a lower end of the second connector to support the second connector.

8. The PIM automatic measurement device according to claim 7, further comprising a fixing part to fix the second plate and the third plate via connection therebetween.

9. The PIM automatic measurement device according to claim 1, wherein the first movement controller and the second movement controller are configured as any one of an air cylinder, a hydraulic pump, and an electric motor.

10. The PIM automatic measurement device according to claim 1, wherein the second connector further comprises a remote electrical tilt (RET) motor to tilt a phase of a signal emitted from an antenna.

11. The PIM automatic measurement device according to claim 1, wherein upward/downward height adjustment and leftward/rightward movement of the first and second connectors are enabled.

12. The PIM automatic measurement device according to claim 1, further comprising a shelf part allowing an radio frequency (RF) component having one or more ports connected to the first and second connectors to be mounted thereon.

13. The PIM automatic measurement device according to claim 12, wherein the shelf part further comprises a vibrator to vibrate the RF component.

14. The PIM automatic measurement device according to claim 12, further comprising a cover member comprising the shelf part therein, an inner wall of the cover member being filled with an electromagnetic wave absorbing material.

15. The PIM automatic measurement device according to claim 1, further comprising a first controller to control ON/OFF of the first and second movement controllers.

16. The PIM automatic measurement device according to claim 10, further comprising a second controller to control a tilt angle of the RET motor.
